(19) United States
(12) Patent Application Publication
(10) Pub. No.: US 2026/0020354 A1
(43) Pub. Date: Jan. 15, 2026

(54) SOLAR CELLS ABSORPTIVE TO SOME PHOTON ENERGIES AND TRANSPARENT TO OTHERS

(71) Applicant: The Regents of the University of California, Oakland, CA (US)

(72) Inventors: Majdi Abou Najm, Davis, CA (US); Jerry M. Woodall, Davis, CA (US)

(73) Assignee: The Regents of the University of California, Oakland, CA (US)

(21) Appl. No.: 19/141,255

(22) PCT Filed: Jan. 4, 2024
(86) PCT No.: PCT/US24/10258

§ 371 Date: Jun. 19, 2025

Related U.S. Application Data
(60) Provisional application No. 63/478,803, filed on Jan. 6, 2023.

(51) Int. Cl. H10F 19/37; A01G 7/04; A01G 9/24; H10F 77/123

(52) U.S. Cl. CPC H10F 19/37; A01G 7/045; A01G 9/249; H10F 77/123

(57) ABSTRACT

A system, apparatus and method are provided for assembling an agriphotovoltaic (APV) system in which solar/photovoltaic cells selectively absorb a first portion or portions of the terrestrial solar spectrum and allow a second portion or portions to pass through to underlying vegetation. For example, solar photons in the green, blue, and ultraviolet (UV) range of the spectrum may be absorbed and used to generate electricity, while other photons (e.g., orange, yellow, and/or red) may be allowed to reach the vegetation. Yet further, a fraction of the generated electricity may be used to generate elements of the first portion(s) of the spectrum (e.g., some blue photons), for transmission toward the vegetation.

### RELATED APPLICATION(S)

This application claims the benefit of U.S. Provisional Patent Application No. 63/478,803, filed 6 Jan. 2023 (docket number UC22-619-1PSP), the contents of which are incorporated by reference herein.

### BACKGROUND

This disclosure relates to the fields of agriculture and photovoltaics. More particularly, an agriphotovoltaic system and apparatus are provided that absorb solar energy for producing electricity while being transparent to solar energy that is most beneficial for growing underlying plants.

Traditional solar energy farms comprising numerous solar panels usually do not coexist well with agriculture. In some scenarios, for example, when solar panels are installed relatively close to the ground and/or are positioned adjacent to each other, underlying vegetation may not receive sufficient solar flux to thrive. Specifically, because conventional solar cells absorb all (or virtually all) the sunlight that impinges upon them, the resulting shading below the cells prevents the underlying crops or vegetation from receiving the sunlight required to stimulate efficient and healthy growth.

Thus, there is interest in the integration of solar cell-produced electricity with commercial crop production, which could conceivably increase land use efficiency to levels exceeding 100% by combining the efficiencies of generation of electricity and crop production on the same land. As an attempt to eliminate the “shading” problem, some attempted solutions reduce the density of solar panels (per area) and elevate the panels to allow for favorable tradeoff between electricity and efficient crop production with less shadowing of the light flux that reaches the crop.

However, this is merely an incremental improvement and an initial effort to allow agriculture and solar-powered photovoltaics to coexist on the same land. What is needed is a way to improve the combined activities to allow both to thrive.

### SUMMARY

In some embodiments, apparatus and methods are provided for efficiently implementing an agriphotovoltaic (APV) system. In these embodiments. the agriphotovoltaic system includes solar/photovoltaic cells that produce electrical energy from one or more portions of the impinging solar spectrum and, simultaneously, deliver to underlying vegetation the remaining portion(s) needed for the vegetation to thrive. Because both power generation and crop lighting are combined in each cell, the cells can be placed immediately adjacent to each other over any desired two-dimensional area (instead of leaving gaps between cells).

For example, in some implementations, the solar cells are opaque or absorptive to solar photons within one or more color ranges of the spectrum (e.g., green, blue, ultraviolet (or UV)) or that have photon energies above a specified energy level (e.g., 2.2 eV). Simultaneously, the solar cells are transparent to photons within other color ranges (e.g., yellow, orange, red, infrared) or having photon energies below the specified energy level.

The solar cells may be illustratively composed of gallium phosphide (GaP), silicon (Si), cadmium telluride (CdTe), or some other element(s) within groups II-VI of the periodic table of elements. Depending on the band gap of the selected material, the thickness of the manufactured cells may be adjusted to yield an apparatus that absorbs and transmits the desired portions of the solar spectrum. For example, a cell composed of (crystalline) silicon may be approximately 3.75 μm (microns) thick while a cell composed of hydrogenated amorphous silicon may be approximately 2 μm thick.

### DESCRIPTION OF THE FIGURES

FIG. 1 is a top perspective view of an agriphotovoltaic (APV) cell in accordance with some embodiments.

FIG. 2 is a bottom perspective view of an APV cell in accordance with some embodiments.

FIG. 3 is a flow chart illustrating a method of using an agrophotovoltaic solar cell, in accordance with some embodiments.

### DETAILED DESCRIPTION

The following description is presented to enable any person skilled in the art to make and use the disclosed embodiments, and is provided in the context of one or more practical applications and their requirements. Various modifications to the disclosed embodiments will be readily apparent to those skilled in the art, and the general principles defined herein may be applied to other embodiments and applications without departing from the scope of those that are disclosed. Thus, the present invention or inventions are not intended to be limited to the embodiments shown, but rather are to be accorded the widest scope consistent with the disclosure.

In some embodiments, systems, apparatus and methods are provided for a more efficient solar cell/crop configuration. Solutions disclosed herein are based on the recognition that the light spectrum needed for optimal crop growth primarily lies in the range of yellow, red, orange, and infrared photons. However, the terrestrial solar spectrum comprises ultraviolet (UV), blue, green, yellow, orange, red, and infrared photons. Therefore, in some embodiments described herein, solar cells are provided that absorb some, most, or all photon energies greater than a threshold (e.g., 2.2 eV) and convert them to electricity, while being transparent to photon energies less than the threshold, which pass through the cells to be absorbed by crops to foster their growth.

Agriphotovoltaics is a growing field that allows for food and energy co-generation, but currently there are no commercially available solar/photovoltaic cells that allow for efficient separation of spectral light between energy generation and food production such that both goals are achieved efficiently and simultaneously in one plot of land with a single cell (or multiple cells of the same or similar type). Solar cells described herein allow for solutions that are customized for different crops. For example, one crop may thrive on solar flux within one range of wavelengths or photon energies, while another crop may thrive on a different range. By tuning a particular solution (e.g., one set of solar cells) to suit the crop(s) that coexist with the solar cells, both industries (agriculture and photovoltaics) benefit.

Some embodiments are provided that employ one or more solar cells that are transparent to solar photons whose energies are at the color boundary between green and yellow. In terms of electron volts, that boundary equates to a photon energy of about 2.2 eV. A solar cell with this band gap energy will be transparent to photons whose energy is less than 2.2 eV and opaque to photons with energies at or above 2.2 eV. The opaque range in these embodiments comprises green, blue and UV photons, while the transparent range comprises red, yellow, and orange photons. The solar cells convert the photons they absorb into current and voltage that can supply electricity to a nearby application or be stored for future use.

Two primary candidate materials that meet the enabling opacity/transparency criteria are gallium phosphide (GaP) and silicon (Si). GaP has a band gap energy of 2.26 eV, but there has been a limited amount of research and development of GaP for the purpose of solar cell applications, and no solar cells have heretofore been produced with efficiencies that approach their quantum limit. Even when the quantum limit efficiencies are achieved, the cost of producing sufficient material for the disclosed embodiments is yet to be determined. Another candidate material is cadmium telluride (CdTe), which illustratively may be sandwiched with cadmium sulfide (CdS) to form the necessary p-n junction.

Alternatively, traditional silicon solar cells are already commercialized as rooftop solar cell arrays, and can be produced at a cost of less than $1/peak watt of output. Unfortunately, the band gap of Si as used in traditional cells is only 1.12 eV, which means a currently available commercial solar cell absorbs all the visible and near infra-red photons emitted by the sun, and would be unsuitable for embodiments in which such photon energies are to be conveyed to underlying crops.

However, a 3.75-micron thick Si solar cell will have an “effective” band gap of 2.2 eV. Technology for producing relatively thin Si solar cells can be leveraged to produce thicker cells for some or all embodiments described herein. Another option is to generate 2-micron thick hydrogenated amorphous Si solar cells with an effective band gap of 2.2 eV for deposition on glass plates or roll-out plastic sheets.

Solar cells for other embodiments may be produced from materials such as zinc (Zn), cadmium (Cd), magnesium (Mg), sulfur (S), selenium (Se) and/or other members of groups II-VI of the periodic table of elements. Compounds of these elements may be used to construct thin, low-cost, direct band gap solar cells having band gap energies in the vicinity of 2.2 eV, and may be deposited on low-cost glass plates or plastic sheets.

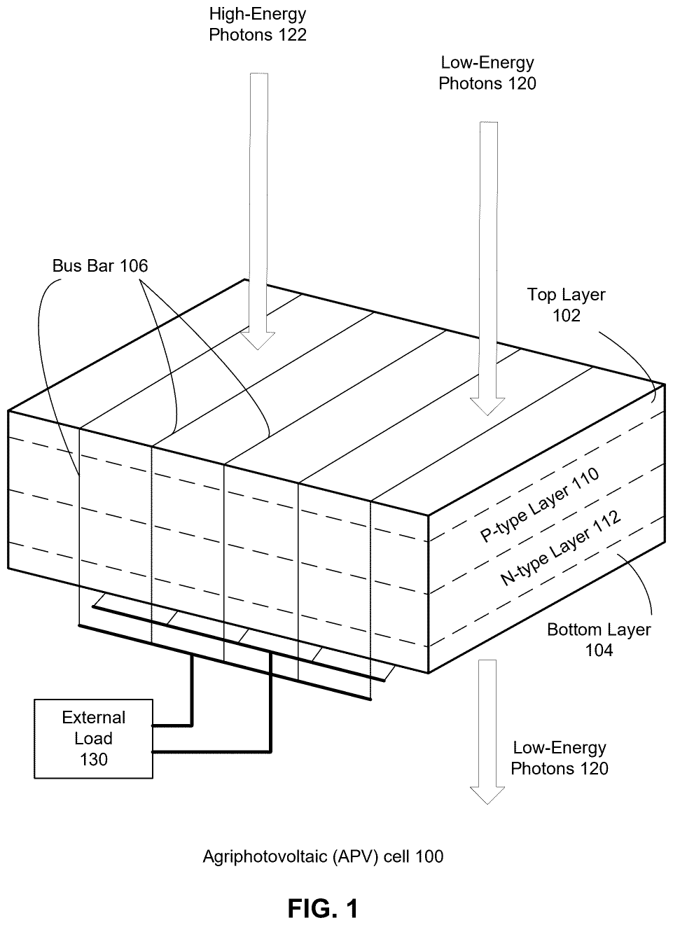

FIG. 1 is a block diagram of an agriphotovoltaic cell according to some embodiments.

In these embodiments, p-type layer 110 and n-type layer 112 are composed of one or more materials identified above, and/or others that are optically transparent to some or all relatively low-energy photons 120 (e.g., yellow, orange, and red wavelengths), which pass through agriphotovoltaic cell 100 to reach underlying plant life. In contrast, high-energy photons 122 (e.g., with green, blue, UV wavelengths) are absorbed by APV cell 100 and converted into electricity to be supplied to load 130.

In some embodiments, electrical conductors are included with APV cell 100 to conduct electricity between the APV cell and the load. The conductors may illustratively comprise bus bars 106, a mesh or grid of fine wires, or some other configuration.

In other embodiments, top layer 102 and/or bottom layer 104 are composed of a transparent conductive oxide (TCO) or transparent conductive film (TCF) for conducting electricity. Illustrative TCOs or TCFs may comprise aluminum-doped zinc oxide (ZnO), gallium-doped ZnO, indium tin oxide (ITO), cadmium oxide (CdO), indium oxide (In₂O₃). gallium oxide (Ga₂O₃), niobium-doped titanium oxide, etc.

An anti-reflective coating (not shown in FIG. 1) may be applied to either surface of top layer 102 and/or bottom layer 104. More specifically, top layer 102 may be enhanced with an anti-reflective coating that reduces or minimizes the reflection of solar photons from p-type layer 110 and/or the top layer. Similarly, bottom layer 104 may be enhanced with an anti-reflective coating that is optimized (e.g., in terms of thickness) to reflect into n-type layer 112 any high-energy photons that may otherwise escape from the bottom layer, while remaining transparent to low-energy photons.

In other embodiments, however, top layer 102 and/or bottom layer 104 may primarily consist of anti-reflective coatings having thicknesses that provide the desired anti-reflection characteristics without impeding low-energy photons. In these embodiments, the top and bottom layers also retain their conductive characteristics to facilitate the collection or distribution of electrical charge.

In some implementations, the combination of p-type layer 110 and n-type layer 112 is a sandwich of crystalline silicon (c-Si) that is approximately 3.75 μm (microns) thick, a sandwich of amorphous silicon (a-Si) approximately 2 μm thick, or a sandwich of GaP that is approximately 10 μm thick. In the p-type layer in a silicon-based APV cell, the silicon is doped with a material (e.g., boron, gallium) that, compared with silicon, possesses one fewer electron in its outer energy level, which causes p-type layer 110 to have an excess of holes compared to n-type layer 112. In these implementations, n-type layer 112 may match the configuration of p-type layer 110, but is instead doped with a material (e.g., phosphorous) that, compared with the silicon, possesses one more electron in its outer energy level, which gives it an excess of electrons compared to p-type layer 110. In other embodiments, the p-type and n-type layers are reversed.

Each relatively high-energy photon that APV cell 100 absorbs creates an electron and a matching hole in p-type layer 110. The electron migrates toward bottom layer 104, while the hole remains in the p-type layer. Accumulation of electrons in n-type layer 112 causes a potential difference between layers 110, 112, which results in the flow of electricity through load 130. Electrons returned to top layer 102 via load 130 recombine with holes in p-type layer 110.

APV cell 100 of FIG. 1 may be constructed on a substrate (not shown in FIG. 1) that provides rigidity and/or flexibility without sacrificing optical transparently. For example, a rigid sheet of glass or plastic, or a rollable sheet of plastic may underlie bottom layer 104.

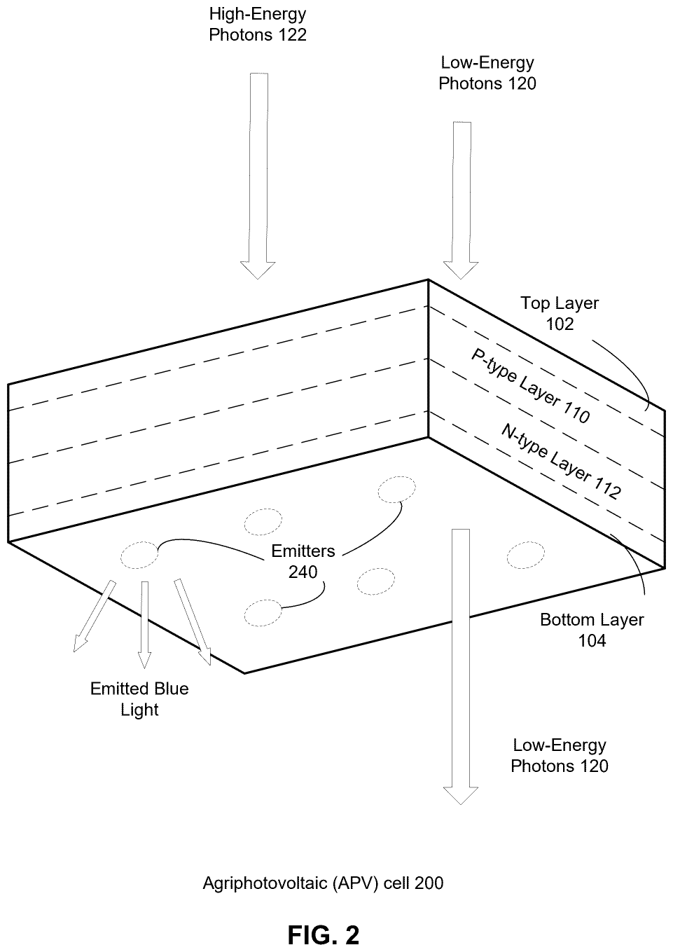

FIG. 2 is a block diagram of an enhanced agriphotovoltaic cell according to some embodiments.

In these embodiments, APV cell 200 is similar or identical to APV cell 100 in many or most respects, but is enhanced or augmented with blue-light emitters 240 attached to bottom layer 104 or an underlying substrate (if o the agriphotovoltaic cell includes a substrate). Emitters 240 may be gallium nitride (GaN) light-emitting diodes (LEDs) in some implementations, but other forms of blue-light emitters may be employed in other implementations. Emitters 240 preferably emit the blue light in a Lambertian manner to provide the blue-light benefit to all plants underlying the APV cell.

In present embodiments, because APV cells described herein allow sufficient portions of the solar spectrum for growing plants underneath the cells, the cells may be placed edge to edge to fully cover a desired area. In different embodiments, the panels may be installed at different heights above the ground or other surface. For example, if mechanized equipment must navigate below the cells, perhaps to harvest underlying crops, sufficient clearance must be provided for the machinery. If the crops are manually harvested, or if the plants themselves are also elevated above the ground (e.g., in raised planting beds or boxes), less clearance may be required.

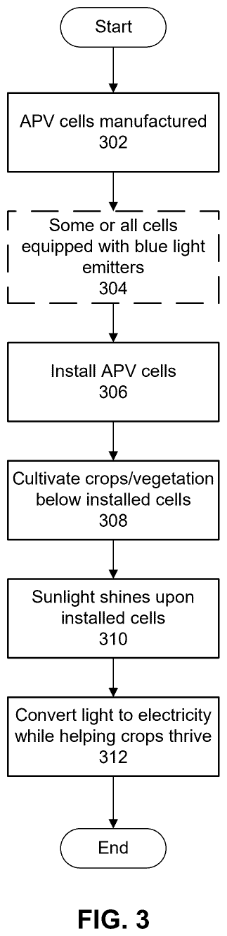

FIG. 3 is a flow chart demonstrating a method of using an agrophotovoltaic (APV) solar cell according to some embodiments. In one or more embodiments, one or more of the operations may be omitted, repeated, and/or performed in a different order. Accordingly, the specific arrangement of steps shown in FIG. 3 should not be construed as limiting the scope of the embodiments.

In operation 302, APV cells are manufactured to include one or more materials that operate as a semiconductor having a band gap energy such that it absorbs one portion of the solar spectrum while being optically transparent to another portion. More particularly, solar photons having energies above the band gap (e.g., green, blue, UV photons) are absorbed by the material(s), while solar photons having energies below the band gap (e.g., red, yellow photons) pass through the material(s) and the solar cells to reach vegetation underlying the cells. Depending on the materials and/or other factors, the cells may or may not include rigid substrates (e.g., glass, plastic).

The APV cells may be enhanced with upper and/or lower anti-reflective layers. An upper layer of an antireflective coating is configured (e.g., its constituent materials, thickness) to allow solar flux to impinge upon the semiconductor material(s), but resist or prevent solar photons (e.g., of all energy levels) from being reflected upward from the material(s). Conversely, a lower layer of an antireflective coating may be configured to allow the lower-energy solar photons to pass through, while reflecting higher-energy photons back toward the semiconductor material(s).

In optional operation 304, the undersides of one or more cells are equipped with blue light emitters. The emitters may be powered with light captured and converted by the APV cells into electricity. The intensity of the emitted light, distances of the emitters from each other, the total number of emitters, and/or other characteristics may differ from one implementation to another, depending upon the distance between the emitters and underlying vegetation, the type of vegetation, whether the APV cells are adjacent to each other or separated by gaps, etc.

In operation 306, the APV solar cells are installed. In some embodiments, the cells are adjacent to each other to form a continuous plane of desired dimensions. In other embodiments the installed cells may be discontinuous. As part of the installation process, the cells are coupled to means for storing electrical energy (e.g., batteries) and/or one or more external loads and, when optional operation 304 is implemented, to the installed blue light emitters. The blue light emitters may, however, be powered in some other manner.

In operation 308, one or more crops or other vegetation are planted or sown below the plane of APV cells. Or, if the vegetation already exists, the APV cells may be installed above them. An initial clearance between the vegetation and the APV cell plane may be selected based on factors such as the expected growth of the vegetation, space needed to tend or harvest the vegetation, operational limitations of blue light emitters installed under the cells, and so on. Because of the shade provided to the crops/vegetation, their water needs may be partially or significantly reduced. Similarly, chicken coops and/or other animal pens may be situated below an arrangement of APV cells and the cells may help reduce temperatures endured by the animals.

In operation 310, sunlight shines upon the APV cells. Light that has energy levels below the band gap of the semiconductor material(s) completely or substantially passes through each cell to reach the vegetation underneath. Meanwhile, light having energy levels above the band gap is substantially absorbed by the material(s) and converted into electricity.

In operation 312, during daylight hours the APV cells promote plant growth by providing the plants with virtually all lower energy wavelengths of light (e.g., red, yellow, orange) that reach the cells, and possibly some blue light as well. Simultaneously, the cells capture higher energy wavelengths of light and convert it to electricity.

An environment in which one or more embodiments described above are executed may incorporate a general-purpose computer or a special-purpose device such as a hand-held computer or communication device. Some details of such devices (e.g., processor, memory, data storage, display) may be omitted for the sake of clarity. A component such as a processor or memory to which one or more tasks or functions are attributed may be a general component temporarily configured to perform the specified task or function, or may be a specific component manufactured to perform the task or function. The term “processor” as used herein refers to one or more electronic circuits, devices, chips, processing cores and/or other components configured to process data and/or computer program code.

Data structures and program code described in this detailed description are typically stored on a non-transitory computer-readable storage medium, which may be any device or medium that can store code and/or data for use by a computer system. Non-transitory computer-readable storage media include, but are not limited to, volatile memory; non-volatile memory; electrical, magnetic, and optical storage devices such as disk drives, magnetic tape, CDs (compact discs) and DVDs (digital versatile discs or digital video discs), solid-state drives, and/or other non-transitory computer-readable media now known or later developed.

Methods and processes described in the detailed description can be embodied as code and/or data, which may be stored in a non-transitory computer-readable storage medium as described above. When a processor or computer system reads and executes the code and manipulates the data stored on the medium, the processor or computer system performs the methods and processes embodied as code and data structures and stored within the medium.

Furthermore, the methods and processes may be programmed into hardware modules such as, but not limited to, application-specific integrated circuit (ASIC) chips, field-programmable gate arrays (FPGAs), and other programmable-logic devices now known or hereafter developed. When such a hardware module is activated, it performs the methods and processes included within the module.

The foregoing embodiments have been presented for purposes of illustration and description only. They are not intended to be exhaustive or to limit this disclosure to the forms disclosed. Accordingly, many modifications and variations will be apparent to practitioners skilled in the art. The scope is defined by the appended claims, not the preceding disclosure.

1. An agriphotovoltaic system comprising:
one or more solar cells, each solar cell comprising a material having a threshold band gap;
wherein photons having energies greater than the threshold band gap are absorbed by the material; and
wherein photons having energies less than the threshold band gap pass through the material.

2. The agriphotovoltaic system of claim 1, wherein the threshold band gap is approximately 2.2 eV.

3. The agriphotovoltaic system of claim 1, further comprising:
vegetation planted in an area underlying the one or more solar cells.

4. The agriphotovoltaic system of claim 1, wherein each of the one or more solar cells further comprises a transparent base.

5. The agriphotovoltaic system of claim 4, wherein the transparent base comprises one or more of:
glass; and
plastic.

6. The agriphotovoltaic system of claim 1, wherein the material converts the absorbed photons into electrical energy.

7. The agriphotovoltaic system of claim 6, wherein plant life underlying the agriphotovoltaic system receives solar flux encompassing only light wavelengths not absorbed by the material of the one or more solar cells.

8. The agriphotovoltaic system of claim 6, wherein:
the material absorbs photons having energies associated with blue light; and
photons having energies associated with red light pass through the one or more solar cells.

9. The agriphotovoltaic system of claim 1, wherein the material comprises gallium phosphide (GaP), silicon (Si), and/or cadmium telluride (CdTe).

10. The agriphotovoltaic system of claim 1, wherein the material comprises one or more of cadmium (Cd), magnesium (Mg), sulfur (S), selenium (Se), and zinc (Zn).

11. The agriphotovoltaic system of claim 1, wherein the material comprises one or more elements from groups II-VI of the periodic table of elements deposited upon a transparent base.

12. The agriphotovoltaic system of claim 1, further comprising:
a connection to an electrical load;
wherein the photons having energies greater than the threshold band gap are converted to electricity supplied to the electrical load; and
wherein the photons having energies less than the threshold band gap are conveyed to vegetation underlying the one or more solar cells.

13. The agriphotovoltaic system of claim 12, wherein the electric load comprises a battery.

14. The agriphotovoltaic system of claim 1, further comprising:
one or more light emitters that emit light principally in blue wavelengths;
wherein a portion of the photons having energies greater than the threshold band gap are converted to electricity supplied to the light emitter; and
wherein the photons having energies less than the threshold band gap are conveyed to vegetation underlying the one or more solar cells.

15. A method of selectively absorbing and passing solar flux, the method comprising:
obtaining one or more solar cells comprising a material that has a predetermined band gap and that converts light energy to electrical energy;
installing the one or more solar cells above the ground; and
growing plant life underneath the one or more solar cells.

16. The method of claim 15, wherein:
the one or more solar cells are optically transparent to photons having energies lower than the band gap; and
the one or more solar cells absorb photons having energies higher than the band gap.

17. The method of claim 16, wherein:
photons having energies lower than the band gap include photons associated with red light; and
photons having energies greater than the band gap include photons associated with blue light.

18. The method of claim 16, wherein:
photons having energies lower than the band gap are more beneficial to growth of the plant life than photons having energies greater than the band gap.

19. The method of claim 16, further comprising:
converting the photons having energies higher than the band gap into electricity; and
supplying the electricity to an external electrical load.

20. The method of claim 16, further comprising:
converting the photons having energies higher than the band gap into electricity; and
supplying the electricity to a light emitter that emits light principally in blue wavelengths;
wherein the emitted light is emitted upon the plant life underneath the one or more solar cells.
